(19) United States
(12) Patent Application Publication
(10) Pub. No.: US 2008/0179657 A1
(43) Pub. Date: Jul. 31, 2008

(54) SEMICONDUCTOR DEVICE HAVING A SELECTIVELY-GROWN SEMICONDUCTOR LAYER

(75) Inventor: Yuki TASAKA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY INC., Tokyo (JP)

(21) Appl. No.: 12/021,122

(22) Filed: Jan. 28, 2008

(30) Foreign Application Priority Data
Jan. 29, 2007 (JP) 2007-018131

(51) Int. Cl. H01L 29/00; H01L 21/76

(52) U.S. Cl. 257/322; 438/429; 257/E21.54; 257/E29.001

(57) ABSTRACT

A semiconductor device includes: a silicon substrate; a first trench formed on a surface portion of the silicon substrate to isolate a plurality of active regions from one another; a first element isolation layer embedded in the first trench; a plurality of selectively-grown silicon layers formed on the respective active regions; and a second element isolation layer embedded in a second trench defined by the top surface of the first element isolation layer and opposing side surfaces of adjacent two of the selectively-grown silicon layers.

This application is based upon and claims the benefit of priority from Japanese patent application No. 2007-018131, the disclosure of which is incorporated herein in its entirety by reference.

### BACKGROUND OF THE INVENTION

1. Field of the Invention

The present invention relates to a semiconductor device having a selectively-grown semiconductor layer and a method of manufacturing the semiconductor device, and more particularly, to the structure of an element isolation layer in the semiconductor device and a method of forming the element isolation layer.

2. Description of the Related Art

DRAM (Dynamic Random Access Memory) devices include an array of memory cells to store therein information or data. Each memory cell includes a MISFET (Metal Insulator Semiconductor Field Effect Transistor) that is formed on the surface portion of a semiconductor substrate, and a capacitor that overlies the semiconductor substrate and is connected to a diffusion region of the MISFET via a conductive plug. The memory cell accumulates charge in the capacitor via the MISFET to store therein the data.

In manufacture of the DRAM devices, prior to forming the MISFETs, an element isolation layer including an insulation material such as silicon oxide or the like is formed on the surface portion of the silicon substrate to isolate element forming regions or active regions from one another, on each of which a MISFET is formed. FIG. 3 shows a top plan view of the arrangement of the element forming regions 104 isolated by the element isolation layer 103 formed on the surface region of the silicon substrate 101. An STI (Shallow Trench Isolation) structure including therein the element isolation layer 103 is generally used, in view of the processing accuracy, wherein the insulation material is embedded in a trench 102.

FIG. 4 is a sectional view illustrating the configuration of the STI-type element isolation layer 103, taken along line IV-IV shown in FIG. 3. The STI-type element isolation layer 103 is formed by the steps of forming the trench 102 on the surface region of the silicon substrate 101, depositing the insulation material over the entire area of the silicon substrate 101 including the internal of the trench 102, and polishing the insulation material by using a CMP (Chemical Mechanical Polishing) process. The CMP process is conducted to flatten the entire surface until the top surface of the silicon substrate 101 is exposed, with the insulation material remaining within the trench 102.

In the STI-type element isolation layer 103, a ratio Y2/X2 referred to as an aspect ratio, which is defined by the width X2 of opening of the trench 102 and the depth Y2 thereof, is generally designed at around three. For instance, in a typical semiconductor device, X2 is 55 nm, Y2 is 165 nm, and the space S2 formed between adjacent opposing portions of the element isolation layer 103 is 55 nm. An excessively higher degree of the aspect ratio may cause an unsatisfactory embedding performance of the insulation material. Therefore, the above value of the aspect ratio or lower should preferably be maintained. The structure of an element isolation layer and the method of forming the element isolation layer are described, for example, in Patent Publication JP-2005-235986-A1.

Meanwhile, along with development of higher integration density of the semiconductor devices, each constituent element in the semiconductor devices is required to have a smaller size, and reduction in the dimensions of the element isolation layer is also desired. However, if the depth of the trench is excessively reduced along with the reduction in the horizontal area of the element isolation layer, a parasitic MISFET may be operated which has a channel region at the lower portion of the shallow element isolation layer and is formed between the diffused regions of adjacent MISFETs. The operation of the parasitic MISFET may cause a malfunction of the semiconductor devices. Therefore, in order to suppress occurring of such a malfunction, it is necessary to maintain the desired depth of the element isolation layer while reducing the width thereof, to thereby prevent the operation of the parasitic MISFET.

### SUMMARY OF THE INVENTION

In view of the above circumstances, it is an object of the present invention to provide a semiconductor device including an element isolation layer having a satisfactorily reduced area while maintaining the desired depth of the trench receiving therein the element isolation layer, and having a moderate aspect ratio of the trench during embedding the insulation material therein.

It is another object of the present invention to provide a method of manufacturing such a semiconductor device.

The present invention provides a semiconductor device including: a semiconductor substrate; a first trench formed on a surface portion of the semiconductor substrate to define a plurality of active regions isolated from one another; a first insulating layer embedded in the first trench; a plurality of selectively-grown semiconductor layers grown on respective the active regions; and a second insulating layer embedded in a second trench defined by a top surface of the first insulating layer and opposing side surfaces of adjacent two of the selectively grown semiconductor layers.

The present invention also provides a method of manufacturing a semiconductor device including: forming a first trench on a surface portion of a semiconductor device to define a plurality of active regions; embedding a first insulating layer in the first trench; selectively growing a plurality of semiconductor layers on respective the active regions; and embedding a second insulating layer in a second trench defined by a top surface of the first insulating layer and opposing side surfaces of adjacent two of the semiconductor layers.

The above and other objects, features and advantages of the present invention will be more apparent from the following description, referring to the accompanying drawings.

### BRIEF DESCRIPTION OF THE DRAWINGS

FIG. 1 is a sectional view showing the structure of a semiconductor device according to an embodiment of the present invention;

FIGS. 2A and 2B are sectional views showing consecutive steps of a process for manufacturing the semiconductor device shown in FIG. 1;

FIG. 3 is a top plan view showing the layout of an element isolation layer and element forming regions of a typical semiconductor device; and

FIG. 4 is a sectional view taken along line IV-IV indicated by the arrow shown in FIG. 3.

### DETAILED DESCRIPTION OF THE INVENTION

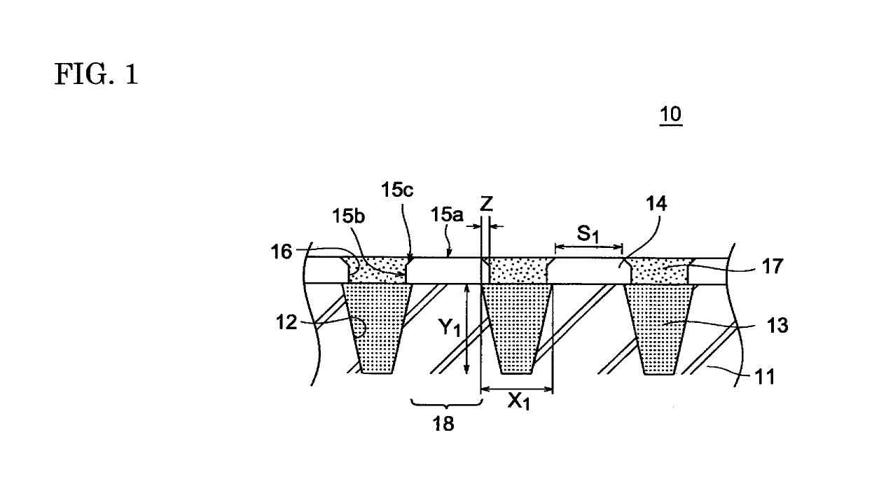

Hereinafter, an exemplary embodiment of the present invention will be described in detail with reference to the accompanying drawings. FIG. 1 is a sectional view showing the structure of a semiconductor device according to the embodiment of the present invention. A semiconductor device 10 is configured as DRAM device and includes a silicon substrate 11. A first trench 12 is formed on the surface region of the silicon substrate 11, and a first isolation layer 13 is embedded in the first trench 12 to configure an STI structure. The first element isolation layer 13 is made of silicon oxide and subjected to planarization using a CMP process to have a top surface flush with the top surface of the silicon substrate 11.

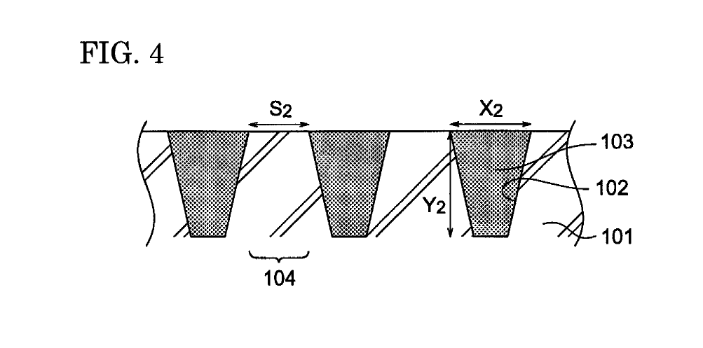

The first element isolation layer 13 has a sectional structure which is reduced in size compared to the conventional STI-type element isolation layer 103 shown in FIG. 4, while maintaining the substantially same aspect ratio as that of the conventional element isolation layer The rate of reduction in the dimensions, i.e., the rate of dimension shrinkage is around 90%. For example, the width X1 of opening of the first trench 12 is 50 nm, the depth Y1 thereof is 150 nm, and the space S1 disposed between adjacent portions of the first element isolation layer 13 is 50 nm.

On the surface portions of the silicon substrate 11 exposed through the first element isolation layer 13, there are formed a plurality of selectively-grown silicon layers 14 deposited using a selective epitaxial growth technique. The surface of the selectively-grown silicon layers 14 includes atop crystalline plane 15a that extends in parallel to the top surface of the silicon substrate 11, a side crystalline plane 15b that extends in a vertical direction, and a corner crystalline plane 15c that is slanted from the vertical direction to couple together the top crystalline plane 15a and the side crystalline plane 15b. The selectively-grown silicon layers 14 protrude horizontally from the boundary between the silicon surface and the first element isolation layer 13, whereby the side crystalline plane 15b is located on the top surface of the first element isolation layer 13.

A second element isolation layer 17 is embedded within a second trench 16, which is defined by the top surface of the first element isolation layer 13 and the crystalline planes 15b and 15c of the selectively-grown silicon layers 14. The second element isolation layer 17 is made of silicon oxide, and the top surface thereof is flush with the top crystalline plane 15a of the selectively-grown silicon layers 14. The first element isolation layer 13 and the second element isolation layer 17 isolate the element forming regions (active regions) 18 from one another, the element isolation regions 18 including the surface portion of the silicon substrate 11 and the selectively-grown silicon layers 14.

On the surface portion of each of the selectively-grown silicon layers 14, there is formed a MISFET (not shown). The gate electrode of the MISFET extends over the selectively-grown silicon layers 14 and the second element isolation layer 17 while intersecting the element forming regions 18. The source/drain diffused regions of the MISFET are formed on the surface portion of the selectively-grown silicon layers 14 adjacent to the gate electrode. A capacitor (not shown) overlies the selectively-grown silicon layers 14, and is connected to the source/drain diffused region of the MISFET via a contact plug.

In the semiconductor device 10 of the present embodiment, the selectively-grown silicon layers 14 are formed on the top surface of the silicon substrate 11 exposed through the STI-type first element isolation layer 13, and the second element isolation layer 17 is embedded in the second trench 16 defined by the top surface of the first element isolation layer 13 and the crystalline planes 15b and 15c of the selectively-grown silicon layers 14. This allows the semiconductor device 10 to have a reduced width of the element isolation layer while maintaining a desired depth of the element isolation layer, without increasing the aspect ratio of the trench during embedding the element isolation layer.

The suppression of the increase in the aspect ratio of the first trench and second trench prevents occurring of an embedding failure when the first insulating layer is embedded into the first trench and the second insulating layer is embedded into the second trench.

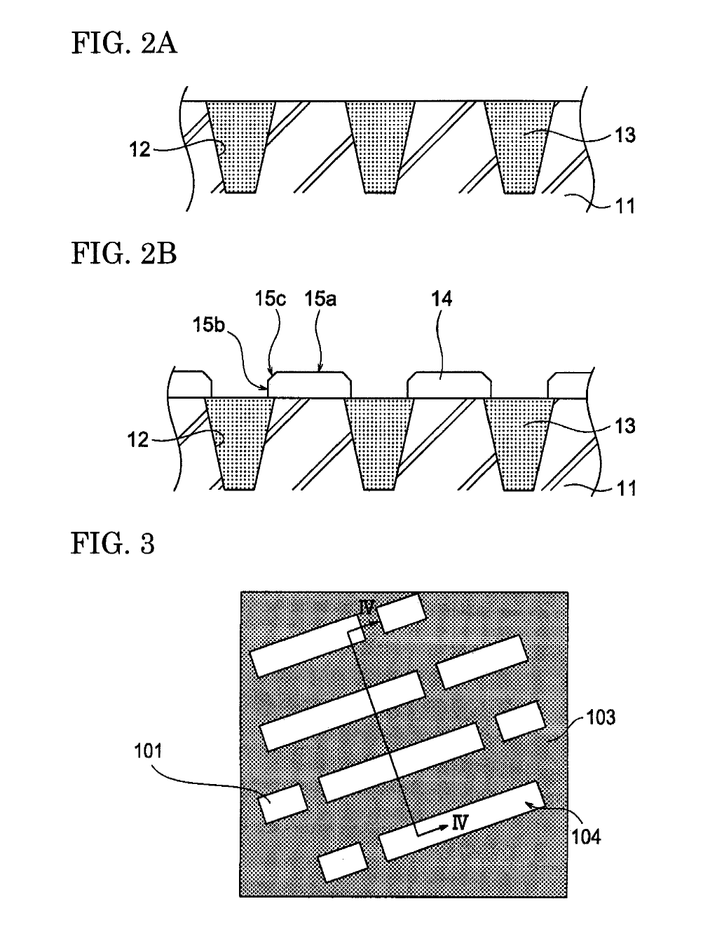

FIGS. 2A and 2B are sectional views showing consecutive steps of a process for manufacturing the semiconductor device 10 shown in FIG. 1. The first trench 12 is first formed on the surface portion of the silicon substrate 11. Thereafter, silicon oxide is deposited over the entire surface area of the silicon substrate 11 including the interior of the first trench 12. Subsequently, by use of a CMP (Chemical Mechanical Polishing) process, the surface portion of the silicon oxide is subjected to a polishing treatment until the top surface of the silicon substrate 11 is exposed, to leave the silicon oxide within the first trench 12, thereby forming the STI-type first element isolation layer 13. The steps up to this step are carried out similarly to those of the conventional process for forming the STI-type element isolation layer except for the dimensions of the element isolation layer, which is reduced to around 90% in the present embodiment.

Subsequently, silicon is grown on the exposed regions of the silicon substrate 11 exposed through the first element isolation layer 13, by using a selective epitaxial growth technique, to thereby form the selectively-grown silicon layers 14. In the selective epitaxial growth process, dichlorosilane, hydrogen chloride and hydrogen are used as a source gas, and are supplied at a flow rate of 50 to 200 sccm (standard cubic centimeters per minute), 30 to 150 sccm, and 10 to 40 slm (standard litters per minute), respectively. The substrate temperature is set within the range of 550 to 800° C. and the total gas pressure is set within the range of 0 to 15 Torr. The time length for the deposition is set to a desired span depending on the thickness of the selectively-grown silicon layers 14 to be grown.

After the selective epitaxial growth process, the surface of the selectively-grown silicon layers 14 has a top crystalline plane 15a that extends in parallel to the surface of the silicon substrate 11, a side crystalline plane 15b that extends in a vertical direction, and a corner crystalline plane 15c that is slanted from the vertical direction. The selectively-grown silicon layers 14 are grown in the direction perpendicular to each of the crystalline planes 15a to 15c. Therefore, the selectively-grown silicon layers 14 are grown in the thickness direction thereof and also in the direction parallel to the surface of the first element isolation layer 13. It is to be noted that the direction of the crystalline plane 15c may be adjusted by controlling the process condition of the selective epitaxial growth process or the like.

As shown in FIG. 1, it is assumed here that X1 is the width of the first element isolation layer 13, and Z is the protruding width of the selectively-grown silicon layers 14 protruding from the interface between the first element isolation layer 13 and the silicon surface and extending on the first element isolation layer 13. If the relation of X1≦2Z is established, the opposing surfaces of adjacent two of the selectively-grown silicon layers 14 are coupled together, with the result that the second trench 16 is not formed. To avoid this configuration, the dimension X1 and the process condition of the selective epitaxial growth process are established so as to satisfy the relation of X1>2Z. Along with the reduction in the dimensions of the first element isolation layer 13, the relation between X1 and Z may easily turn out X1≦2Z. Therefore, particular attention is required to satisfy the relation of X1>2Z.

Subsequently, silicon oxide is deposited on the entire surface of the silicon substrate 11 including the interior of the second trench 16 defined by the top surface of the first element isolation layer 13 and the crystalline planes 15b and 15c of the selectively-grown silicon layers 14. Subsequently, by use of a CMP process, the resultant surface is subjected to planarization until the top crystalline plane 15a of the selectively-grown silicon layers 14 is exposed, to leave the deposited silicon oxide within the second trench 16, thereby forming the second element isolation layer 17 to isolate the element forming regions 18 from one another.

The gate electrode (not shown) extending across the element forming regions 18 is then formed to overlie the selectively-grown silicon layers 14 and the second element isolation layer 17. Thereafter, the surface portion of the selectively-grown silicon layers 14 adjacent to the gate electrode is doped with impurities, to form source/drain diffused regions (not shown) of the MISFET. The above process provides the MISFET including the gate electrode and the source/drain diffused regions. Further, the capacitors (not shown) are formed to overlie the selectively-grown silicon layers 14 and are connected to the source/drain diffused region of the MISFETs via a contact plug.

In accordance with the method of manufacturing the semiconductor device of the present embodiment, it is possible to suppress increase of the aspect ratio of the first trench 12 and that of the second trench 16. Therefore, an embedding failure can be avoided when the first element isolation layer 13 and the second element isolation layer 17 are embedded into the first trench 12 and the second trench 16, respectively.

Further, in the process of selective epitaxial growth, the selectively-grown silicon layers 14 extend onto the top surface of the first element isolation layer 13, whereby the second element isolation layer 17 may have a smaller width, and effectively reduces the occupied area of the top element isolation layer. It is to be noted that the first element isolation layer 13 and the second element isolation layer 17 are not limited to silicon oxide, and t may be made of silicon nitride, silicon oxynitride, or the like.

While the invention has been particularly shown and described with reference to exemplary embodiment and modifications thereof, the invention is not limited to these embodiment and modifications. It will be understood by those of ordinary skill in the art that various changes in form and details may be made therein without departing from the spirit and scope of the present invention as defined in the claims.

For example, in the above embodiment, the semiconductor device described therein is a DRAM device. However, the present invention is applicable to variety of types of semiconductor devices including MISFETs on the surface portions of a semiconductor substrate.

What is claimed is:

1. A semiconductor device comprising:
a semiconductor substrate;
a first trench formed on a surface portion of said semiconductor substrate to isolate a plurality of active regions from one another;
a first insulating layer embedded in said first trench;
a plurality of selectively-grown semiconductor layers grown on respective said active regions; and
a second insulating layer embedded in a second trench defined by a top surface of said first insulating layer and opposing side surfaces of adjacent two of said selectively grown semiconductor layers.

2. The semiconductor device according to claim 1, wherein said semiconductor layers protrude from respective said active regions toward said first insulation layer.

3. The semiconductor device according to claim 1, wherein said active regions are designed to receive therein source/drain regions of MISFETs.

4. The semiconductor device according to claim 1, wherein both said semiconductor substrate and said selectively grown semiconductor layer include silicon.

5. A method of manufacturing a semiconductor device comprising:
forming a first trench on a surface portion of a semiconductor device to isolate a plurality of active regions from one another;
embedding a first insulating layer in said first trench;
selectively growing a plurality of semiconductor layers on respective said active regions; and
embedding a second insulating layer in a second trench defined by a top surface of said first insulating layer and opposing side surfaces of adjacent two of said semiconductor layers.

6. The method of manufacturing a semiconductor device according to claim 5, wherein said semiconductor substrate and said semiconductor layer include silicon.

7. The method of manufacturing a semiconductor device according to claim 5, wherein said second insulating layer includes at least one of silicon oxide and silicon nitride.
